(19) United States
(12) Patent Application Publication
(10) Pub. No.: US 2002/0072227 A1
(43) Pub. Date: Jun. 13, 2002

(54) Method for improving barrier properties of refractory metals/metal nitrides with a safer alternative to silane

(76) Inventors: Noel Russell, Plano, TX (US); Richard A. Faust, Plano, TX (US); Robert E. Yui, Richardson, TX (US); Jiong-Ping Lu, Richardson, TX (US)

Correspondence Address: TEXAS INSTRUMENTS INCORPORATED, P O BOX 655474, M/S 3999, DALLAS, TX, 75265

(21) Appl. No.: 09/938,207

(22) Filed: Aug. 23, 2001

Related U.S. Application Data
(60) Provisional application No. 60/227,544, filed on Aug. 24, 2000.
(60) Provisional application No. 60/250,224, filed on Nov. 30, 2000.

(51) Int. Cl. H01L 21/44

(52) U.S. Cl. 438/653

(57) ABSTRACT

A barrier/liner structure (10) and method. First, a refractory metal/metal nitride layer (12) is formed over a structure (18), for example, by metal-organic CVD (MOCVD). Then, the refractory metal/metal nitride layer (12) is exposed to an organosilane, such as diethylsilane, to obtain a silicon-rich surface layer (14).

### CROSS-REFERENCE TO RELATED APPLICATIONS

The following co-pending U.S. patent application is related and hereby incorporated by reference:

| Serial No. | Filed | Inventors |
|---|---|---|
| 09/645,157 | August 24, 2000 | Lu et al. |

### FIELD OF THE INVENTION

This invention generally relates to the semiconductor devices and their fabrication, and more specifically to barrier/liner films for metal interconnects.

### BACKGROUND OF THE INVENTION

Barrier/liner films are critical components in multilevel interconnect technology, particularly important for Cu and Al metalization. Cu is known to be able to diffuse into Si, SiO₂ and other dielectric films. Al in contact with Si or suicides has problems associated with “junction-spiking”. Good gap-fill of Cu/Al also requires a proper liner to help reflow. High quality barrier/liner films are therefore essential for the success of both Cu and Al metalization.

The most common barrier films used in microelectronics industry today are refractory metal nitride, such as TiN, thin films. TiN-based barrier films may be prepared by physical vapor deposition (PVD) using reactive sputtering, with or without collimation. However, sputtering is a line-of-sight technique and produces films with poor step coverage. As the minimum feature size shrinks and the aspect ratio of contact/via/trench increases, processes that produce conformal films are required. Another problem associated with PVD films is that the films have columnar structures and provide easy diffusion paths. This is particularly severe when device minimum feature continues to shrink and thickness of barrier/liners continues to decrease.

Chemical-vapor-deposition (CVD) processes deposit films with improved step coverage. Two types of CVD processes are used currently: one based on inorganic precursors, such as TiCl₄/NH₃, and the other based on metal-organic precursors, such as tetrakis(dimethylamino)-titanium (TDMAT) and tetrakis(diethylamino)-titanium (TDEAT). The inorganic based processes require high deposition temperatures (>550° C.), leave corrosive impurities (e.g. Cl) in the films and have problems associated with particulate formation (e.g. NH₄Cl). Thermal decomposition of TDMAT or TDEAT produces films with high resistivity, which increases upon exposure to air. Adding NH₃ into the reactant mixture improves the resistivity; however, the step coverage is adversely affected and NH₃ addition introduces gas phase reactions, a potential source for particle generation. An in-situ plasma treatment of TDMAT thermal decomposed films was also reported. However, this process has very low throughput due to limited penetration depth of plasma and requires special hardware.

To solve the above problems, MOCVD TiN films were treated with silane. Treatment with silane greatly improved the resistance of the film to unwanted copper diffusion. The improvement in barrier properties is believed to be the result of a thin layer of silicon being deposited into the grain boundaries, pores and other interstices of the film. This serves to block these fast pathways for diffusion. Unfortunately, silane is a pyrophoric gas that is heavily regulated and expensive to use safely.

### SUMMARY OF THE INVENTION

A silicon treated barrier/liner structure and method are disclosed herein. First, a refractory metal-based film is formed over a structure. Examples include TiN, Ta, TaN, TaC, W, WN, and TiW deposited by CVD or PVD. Then, the refractory-metal-based film is exposed to an organosilane such as diethylsilane to obtain a silicon-rich surface layer.

An advantage of the invention is providing a safer method of treating a barrier/liner with silicon compared to treating with silane.

This and other advantages of the invention will be apparent to those of ordinary skill in the art having reference to the specification and drawings.

### BRIEF DESCRIPTION OF THE DRAWINGS

In the drawings:

FIG. 1 is a cross-sectional diagram of a barrier/liner according to the invention;

FIGS. 2A-2E are cross-sectional diagrams of the barrier/liner of FIG. 1 at various stages of fabrication; and

FIG. 3 is a cross-sectional diagram of an alternative embodiment of the invention.

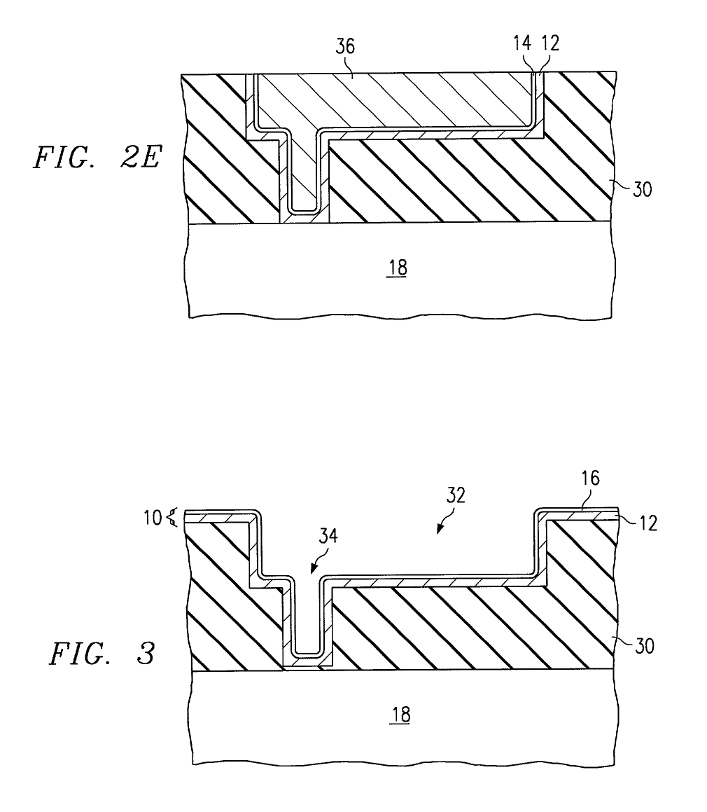

Corresponding numerals and symbols in-the different figures refer to corresponding parts unless otherwise indicated.

### DETAILED DESCRIPTION OF PREFERRED EMBODIMENTS

The invention is a barrier/liner and will be described in conjunction with a dual damascene copper interconnect process. However, it will be apparent to those of ordinary skill in the art that the benefits of the inventions may be applied to other barrier/liner applications.

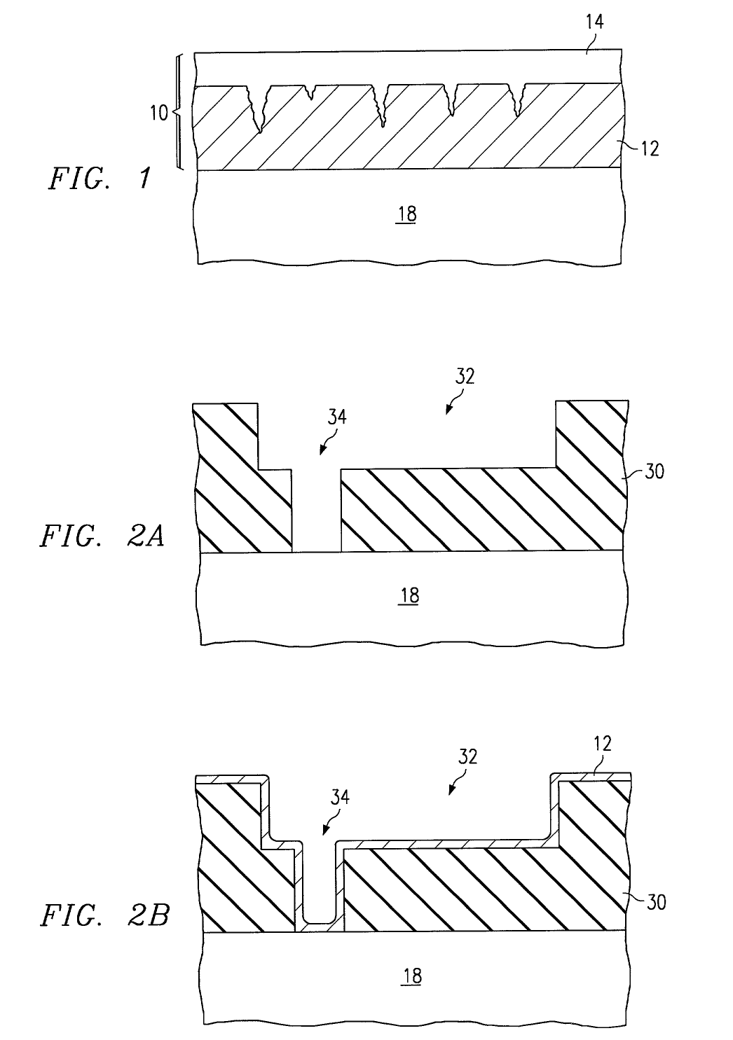

FIG. 1 is an expanded view of a cross-section of the barrier/liner 10 according to the invention. Barrier/liner 10 is located over a semiconductor body 18. Barrier/liner 10 comprises a refractory metal-based layer 12. Layer 12 may, for example, comprise refractory metals, refractory-metal nitrides, or refractory metal-carbides. Specific example materials for refractory metal-based layer 12 include TiN, Ta, TaN, TaC, W, WN, and TiW.

Refractory metal-based layer 12 is preferably a porous layer that allows a silicon-rich surface layer 14 to extend therein. The silicon rich surface layer 14 may be in the range of 1 Å to 10 Å thick. The function of silicon-rich surface layer 14 is to block diffusion paths in the refractory metal-based layer 12 and prevent the diffusion of copper metal through the barrier/liner layer 10 into the dielectric.

While the prior art uses a silane treatment to form silicon-rich surface layer 14, the present invention uses an organosilane such as diethylsilane (DES), diisopropylsilane, or ditertbutylsilane. The use of silane, as in the prior art, presents unique safety challenges on metal deposition tools that are typically cryopumped. This is due to the possibility of residual gases co-adsorbed in the cryopump along with oxygen and water forming an explosive mixture when the cryopump is regenerated and these gases are rapidly evolved. Organosilanes, on the other hand, have significantly lower reactivity with oxygen and water, so they are not pyrophoric and may be safely handled in air. A subset of this class of compounds substituted with aliphatic groups is capable of undergoing β-hydride elimination can react under very similar conditions to silane, resulting in silicon deposition. DES reacts via a β-hydride elimination to leave a hydrogen terminated silicon surface. The β-hydride elimination occurs at a temperature lower than that required for silicon deposition, so pure silicon can be deposited with similar kinetics as deposition from silane.

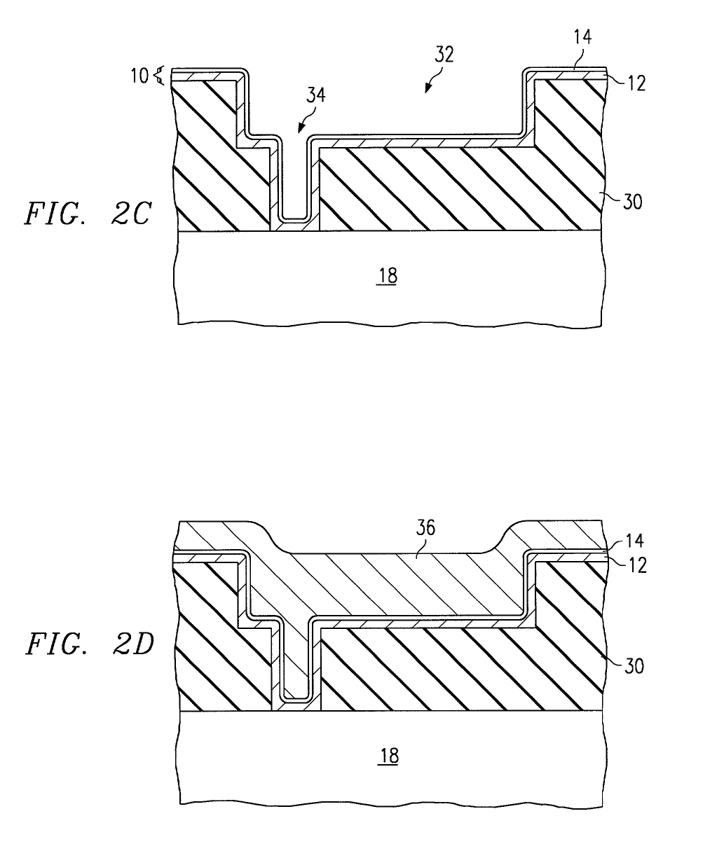

A process for forming barrier/liner 10 according to the invention will now be described in conjunction with FIGS. 2A-2C. FIG. 2A shows semiconductor body 18 processed as desired and prepared for the formation of a barrier/liner. For example, semiconductor body 18 may be processed through the formation dielectric layer 30. Dielectric layer 30 represents a combined interlevel dielectric and intrametal dielectric typical for dual damascene copper interconnects. A trench 32 is formed in dielectric layer 30. A metal interconnect line will subsequently be formed in trench 32. Via 34 is also formed in dielectric layer 30. Via 34 extends from the bottom of trench 32 to a lower metal interconnect layer (not shown) to connect between metal interconnect layers.

The barrier/liner 10 is formed on the surface of dielectric layer 30 including within trench 32 and via 34. Referring to FIG. 2B, the process begins with the deposition of a refractory metal-based film 12. As discussed above, the refractory metal-based film may, for example, comprise TiN, Ta, TaN, TaC, W, WN, or TiW. TiN, Ta, TaN, TaC, W, or WN may be deposited in a CVD reactor system, such as Applied Materials' model P-5000. Example processing conditions described below are based on this reactor and actual processing condition will vary somewhat depending on the type of CVD reactor used. Alternatively, a PVD process may be used, for example, to deposit Ta, TaN or TiW.

A preferred embodiment of this step deposits TiN by the thermal decomposition of TDMAT. However, other metal organic precursors may alternatively be used for a MOCVD process. The semiconductor body 18 is first transferred to a pre-heated sample holder (with typical temperatures in the range of 375-450□ C.) in a CVD reactor. The TDMAT liquid precursor is then introduced into the reactor using He carrier gas (or other inert gases) for a designated duration based on thickness requirement. Films deposited by this step have a porous structure and contain Ti, N and C. Some typical processing conditions are summarized as follows:

TABLE I
Typical Processing Conditions for Step 101

| | |
|---|---|
| TDMAT flow: | 10-500 sccm |
| N₂ diluent flow: | 50-500 sccm |
| Susceptor Temp: | 375-500 □C |
| Reactor Pressure: | 0.2-5 torr |

As a result, a refractory-metal based film having a thickness in the range of 5 Å-50 Å is deposited.

Alternatively, refractory metal-based film 12, may be formed using a PVD process. As deposited (by PVD), these refractory metal/nitrides typically have a columnar grain structure. In this embodiment, Si is deposited in these grain boundaries to hinder diffusion between the grains of the material.

Referring to FIG. 2C, the refractory metal-based film (layer 12) is then exposed to an organosilane. This step can be performed in the same chamber as the refractory metal-based film deposition or in a separate chamber in the same cluster tool. The susceptor temperature is preferably in the range of 200-450° C. Some typical processing conditions for this step are summarized as follows:

TABLE II
Typical Processing Conditions for Step 102

| | |
|---|---|
| DES flow: | 1-100 sccm |
| Susceptor Temp: | 200-450 □C |
| Reactor Pressure: | 10 mTorr-760 Torr |

The organosilane may be delivered in pure form or diluted with a carrier gas such as He or Ar. The process results in a silicon-rich surface layer 14 having a thickness in the range of 1 Å to 10 Å.

Organosilanes have significantly lower reactivity with oxygen and water, so they are non-pyrophoric compounds that are safer to use and present no explosion hazard on metallization tools. Thus, they may be used with less stringent regulations. A subset of this class of compounds substituted with aliphatic groups is capable of undergoing β-hydride elimination can react under very similar conditions to silane, resulting in silicon deposition. For example, the ethyl groups of DES react via β-hydride elimination to evolve ethylene at a temperature lower than that employed in the silane treatment process, leaving a hydrogen terminated silicon surface. The rate of deposition is controlled by hydrogen desorption, identical to the kinetics involved in deposition from silane. Examples of suitable organosilanes include diethylsilane (DES), diisopropylsilane, and ditertbutylsilane.

The resulting silicon-rich surface layer 14 fills the pores and grain boundaries of the refractory metal-based film 12. Thus, diffusion of metals such as copper is prevented as in the prior art. However, a safer process is used.

After the silicon surface treatment with an organosilane, a copper interconnect may be formed. Typically, a copper seed layer is deposited over barrier/liner 10. Electrochemical deposition (ECD) is then used to fill the via 34 and trench 32 with copper 36, as shown in FIG. 2D. Excess copper 36 as well as portions of the barrier/liner 10 over the top surface dielectric layer 30 are then chemically-mechanically polished to form the copper interconnect, as shown in FIG. 2E. Processing may then continue to form addition metal interconnect layers and ultimately package the devices.

Alternate Process Embodiments

The novel approach described herein can have different process embodiments than those described above. As an example, the starting precursor is not necessary to be TDMAT. Alternate precursors include: tetrakis (dimethylamindo) titanium (TDEAT) and tetrakis (methylethylamindo) titanium (TMEAT). It can also be other transition metal (e.g. W and Ta) organometallic precursors, if alternate barriers containing W and Ta instead of Ti are needed.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for fabricating an integrated circuit, comprising the steps of:
forming a refractory metal-based layer over a semiconductor body; and
exposing said refractory metal-based layer to an organosilane to obtain a silicon-rich surface layer.

2. The method of claim 1, wherein said organosilane comprises diethylsilane.

3. The method of claim 1, wherein said organosilane comprises diisopropylsilane.

4. The method of claim 1, wherein said organosilane comprises ditertbutylsilane.

5. The method of claim 1, wherein the step of forming the refractory metal-based layer comprises the step of chemical-vapor deposition using a metal-organic precursor.

6. The method of claim 5, wherein said chemical vapor depositing step further comprises the step of heating the structure to a temperature in the range of 300-450□ C.

7. The method of claim 1, wherein the step of forming the refractory metal-based layer comprises the step of chemical-vapor depositing TiN.

8. The method of claim 1, wherein the step of forming the refractory metal-based layer comprises the step of chemical-vapor depositing Ta.

9. The method of claim 1, wherein the step of forming the refractory metal-based layer comprises the step of chemical-vapor depositing TaN.

10. The method of claim 1, wherein the step of forming the refractory metal-based layer comprises the step of chemical-vapor depositing TaC.

11. The method of claim 1, wherein the step of forming the refractory metal-based layer comprises the step of chemical-vapor depositing W.

12. The method of claim 1, wherein the step of forming the refractory metal-based layer comprises the step of chemical-vapor depositing WN.

13. The method of claim 1, wherein the step of forming the refractory metal-based layer comprises the step of physical vapor depositing a material selected from the group consisting of Ta, TaN and TiW.

14. The method of claim 1, wherein said step of exposing the refractory metal-based layer to an organosilane occurs at a temperature in the range of 200-450° C.

15. The method of claim 1, wherein said step of exposing the refractory metal-based layer to an organosilane occurs at a pressure in the range of 10 m Torr-760 Torr.

16. The method of claim 1, wherein said organosilane is diluted with a carrier gas.

17. A method of fabricating a copper interconnect of an integrated circuit, comprising the steps of:
forming a dielectric layer over a semiconductor body;
forming a trench in said dielectric layer;
forming a refractory metal-based layer over said dielectric layer including within said trench;
exposing said refractory metal-based layer to an organosilane to obtain a silicon-rich surface layer; and
forming a copper layer over said silicon-rich surface layer.

18. The method of claim 17, wherein said organosilane is selected from the group consisting of diethylsilane, diisopropylsilane, a ditertbutylsilane.

19. The method of claim 17, wherein said refractory metal-based layer is chemically vapor deposited and selected from the group consisting of TiN, Ta, TaN, TaC, W, and WN.

20. The method of claim 17, wherein said refractory metal-based layer is physically vapor deposited and selected from the group consisting of Ta, TaN, and TiW.

21. The method of claim 17, wherein said step of exposing the refractory metal-based layer to an organosilane occurs at a temperature in the range of 200-450° C.

22. The method of claim 17, wherein said step of exposing the refractory metal-based layer to an organosilane occurs at a pressure in the range of 10 m Torr-760 Torr.

23. The method of claim 17, wherein said organosilane is diluted with a carrier gas.
